(19) United States
(12) Patent Application Publication
(10) Pub. No.: US 2018/0158971 A1
(43) Pub. Date: Jun. 7, 2018

(54) TRANSPARENT PHOTOELECTRIC ELEMENT AND METHOD FOR FABRICATING THE SAME

(71) Applicant: Incheon University Industry Academic Cooperation Foundation, Incheon (KR)

(72) Inventors: Joon Dong Kim, Incheon (KR); Malkeshkumar PATEL, Incheon (KR)

(21) Appl. No.: 15/827,965

(22) Filed: Nov. 30, 2017

(30) Foreign Application Priority Data
Dec. 5, 2016 (KR) 10-2016-0164143

(51) Int. Cl. H01L 31/0224; H01L 31/0236; H01L 31/02; H01L 31/18; H01L 21/02; H01L 31/0352; H01L 31/0392

(52) U.S. Cl. CPC H01L 31/022475; H01L 31/022483; H01L 31/02366; H01L 31/0392; H01L 31/1884; H01L 21/02422; H01L 31/035218; H01L 31/02008

(57) ABSTRACT

A transparent photoelectric element and a method for fabricating the same are provided. The method includes providing a transparent substrate, forming a transparent conductive film on the transparent substrate at room temperature, forming an n-type oxide semiconductor film on the transparent conductive film and forming a p-type nickel oxide film having a quantum dot structure on the n-type oxide semiconductor film through reactive sputtering at room temperature, the reactive sputtering including oxygen and argon, a ratio of oxygen being smaller than a ratio of argon.

This application claims priority from Korean Patent Application No. 10-2016-0164143 filed on Dec. 05, 2016 in the Korean Intellectual Property Office, the disclosure of which is incorporated herein by reference in its entirety.

### BACKGROUND OF THE INVENTION

### 1. Field of the Invention

The present invention relates to a transparent photoelectric element and a method for fabricating the same. More specifically, the present invention relates to a transparent photoelectric element having high transparency and high conversion efficiency and a method for fabricating the same.

### 2. Description of the Related Art

Global warming is a fatal problem for human beings living on Earth. Past energy production has been mainly accompanied by the generation of greenhouse gas, in which a composition ratio of the Earth's atmosphere has significantly increased, and such greenhouse gas has caused a sea level rise and the destruction of ozone responsible for filtering of ultraviolet rays. Due to the increase in the greenhouse gases, human beings are experiencing the shortage of the area of the living earth and the shortage of breath oxygen. Furthermore, excessive ultraviolet radiation comes into direct-contact with the human body, which causes severe risks such as skin discoloration, immune function deterioration, photo-aging and skin cancer.

Energy production using solar cells is one of the ultimate forms of electricity generation performed without the production of greenhouse gases. However, since conventional general solar cells include dark semiconductor films (or wafers), they have clear transparency limitation in direct application to the on-site energy generation of buildings or vehicles.

### SUMMARY OF THE INVENTION

An aspect of the present invention provides a transparent photoelectric element with improved operating performance.

Another aspect of the present invention provides a method for fabricating a transparent photoelectric element with improved operating performance.

The aspects to be solved by the present invention are not limited to the aspects mentioned above and another aspect which is not mentioned can be clearly understood by those skilled in the art from the description below.

According to an aspect of the present inventive concept, there is provided a method for fabricating a transparent photoelectric element, the method comprising providing a transparent substrate, forming a transparent conductive film on the transparent substrate at room temperature, forming an n-type oxide semiconductor film on the transparent conductive film and forming a p-type nickel oxide film having a quantum dot structure on the n-type oxide semiconductor film through reactive sputtering at room temperature, the reactive sputtering including oxygen and argon, a ratio of oxygen being smaller than a ratio of argon.

According to another aspect of the present inventive concept, there is provided a transparent photoelectric element comprises a transparent flexible PET (polyethylene terephthalate) substrate, a transparent conductive film formed on the transparent flexible PET substrate, the transparent conductor including ITO (Indium Tin Oxide) or FTO (fluorine-doped tin oxide), an n-type oxide semiconductor film formed on the transparent conductive film and a p-type nickel oxide film formed on the n-type oxide semiconductor film and forming a heterojunction with the n-type oxide semiconductor film, wherein exciton occurs in the heterojunction, and the p-nickel oxide film has a quantum dot structure.

According to still another aspect of the present inventive concept, there is provided a transparent photoelectric element comprising a first laminated structure which includes a first glass substrate, a first transparent conductor film formed on the first glass substrate, a first FTO film formed on the first transparent conductor film, and a first NiO film formed on the first FTO film and forming a heterojunction with the first FTO film, a second laminated structure which includes a second glass substrate, a second transparent conductor film formed on the second glass substrate, a second FTO film formed on the second transparent conductor film, and a second NiO film formed on the second FTO film and forming a heterojunction with the second FTO film and a bonding wire which connects the first and second laminated structures

According to an embodiment of the present invention, at least the following effects are obtained.

That is, the transparent photoelectric element according to some embodiments of the present invention is wholly completely transparent, flexible and cuttable.

Also, the transparent photoelectric element according to some embodiments of the present invention can have a high open voltage and a very fast reaction rate.

Furthermore, the transparent photoelectric element according to some embodiments of the present invention can have the highest efficiency of the transparent solar cell.

The effects of the present invention are not limited by the contents exemplified above, and various effects are further included in this specification.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The above and other aspects and features of the present invention will become more apparent by describing in detail exemplary embodiments thereof with reference to the attached drawings, in which:

FIGS. 1 to 3 are intermediate stage diagrams for explaining a method for fabricating a transparent photoelectric element according to a first example of the present invention;

FIG. 4 is a digital photograph of the transparent photoelectric element of the first example fabricated using the method for fabricating the transparent photoelectric element of FIGS. 1 to 3;

FIG. 5 is a FESEM (field emission scanning electron microscope) photograph of a surface of a nickel oxide film formed in the method for fabricating the transparent photoelectric element of FIGS. 1 to 3;

FIG. 6 is a HRTEM (high-resolution transmission electron microscopy) photograph of a nickel oxide film fabricated by a reactive sputtering method;

FIG. 7 is an FESEM photograph of the surface of an ITO (Indium Tin Oxide) film formed in the method for fabricating the transparent photoelectric element of FIGS. 1 to 3;

FIG. 8 is an FESEM photograph of the surface of the zinc oxide film formed in the method for fabricating the transparent photoelectric element of FIGS. 1 to 3;

FIG. 9 is a graph illustrating transmittance, reflectance and absorbance spectra of the transparent photoelectric element according to the first example of the present invention;

FIG. 10 is a diagram for explaining a cutting method of a transparent photoelectric element according to the first example of the present invention;

FIG. 11 is a diagram illustrating TEM (transmission electron microscopy) and EDS (energy-dispersive X-ray spectroscopy) for cross-sectional analysis of the transparent photoelectric element according to the first example of the present invention;

FIG. 12 is a diagram illustrating a test scene in which ultraviolet rays of 365 nm are incident on the transparent photoelectric element according to the first example of the present invention;

FIG. 13 is a graph illustrating the current-voltage characteristics of the transparent photoelectric element according to the test of FIG. 12 under the pulsed incident light condition;

FIG. 14 is a graph illustrating the zero bias device operation of the transparent photoelectric element according to the first example of the present invention and the effects of the light intensity of the instantaneous photoresponse;

FIG. 15 is a graph for instantaneous photoresponse analysis of the transparent photoelectric element according to the first example of the present invention;

FIG. 16 is a graph for explaining the photoresponse and the bias effect of the transparent photoelectric element according to the first example of the present invention;

FIG. 17 is a graph for explaining an instantaneous photoresponse of the transparent photoelectric element according to the first example of the present invention;

FIG. 18 is a graph for explaining current-voltage characteristics of the transparent photoelectric element according to the first example of the present invention;

FIG. 19 is a digital photograph for explaining an arrangement of a transparent photoelectric element of a second example of the present invention;

FIG. 20 is a diagram for explaining the series connection of the transparent photoelectric elements according to the second example of the present invention;

FIG. 21 is a diagram for explaining the parallel connection of the transparent photoelectric elements according to the second example of the present invention;

FIG. 22 is a graph illustrating the transmittance of the transparent photoelectric element of the second example of the present invention;

FIG. 23 is a diagram for explaining the voltage-current characteristics of the transparent photoelectric element unit of the second example of the present invention;

FIG. 24 is a conceptual diagram for explaining generation of exciton of a transparent photoelectric element according to some embodiments of the present invention;

FIG. 25 is a conceptual diagram for explaining utilization of ultraviolet rays of the transparent photoelectric element according to some embodiments of the present invention;

FIG. 26 is an energy band diagram for explaining energy levels in a balanced condition of the transparent photoelectric element according to some embodiments of the present invention;

FIG. 27 is an energy band diagram for explaining an energy level when a transparent photoelectric element according to some embodiments of the present invention forms exciton; and

FIG. 28 is a graph for explaining a photoluminescence spectrum of the transparent photoelectric element according to some embodiments of the present invention.

### DETAILED DESCRIPTION OF THE INVENTION

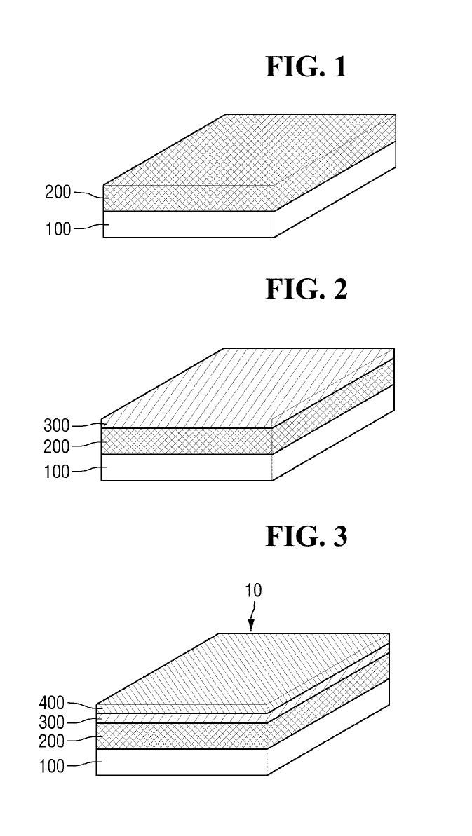

Hereinafter, a method for fabricating a transparent photoelectric element according to some embodiments of the present invention will be described with reference to FIGS. 1 to 3.

FIGS. 1 to 3 are intermediate stage diagrams for explaining a method for fabricating a transparent photoelectric element according to some embodiments of the present invention.

Referring to FIG. 1, a transparent substrate 100 is provided.

The transparent substrate 100 may be, for example, a flexible substrate. That is, the transparent substrate 100 may have characteristics that are freely bent and then restored. In this case, the transparent substrate 100 may be a plastic substrate. At this time, the transparent substrate 100 may be, for example, a PET (polyethylene terephthalate) substrate.

The transparent substrate 100 may not be a flexible substrate. The transparent substrate 100 may also be a transparent glass substrate. The material of the transparent substrate 100 may vary depending on the performance and purpose of the device.

The transparent substrate 100 may be a substrate without any color.

Subsequently, a transparent conductive film 200 is formed on the transparent substrate 100.

The transparent conductive film 200 may include ITO or FTO. The transparent conductive film 200 may be formed by sputtering at room temperature.

Subsequently, referring to FIG. 2, an n-type oxide semiconductor film 300 is formed on the transparent conductive film 200.

The n-type oxide semiconductor film 300 may include at least one of ZnO, AZO, TiO and SnS. The n-type oxide semiconductor film 300 may also be a transparent film material. The n-type oxide semiconductor film 300 may be formed by RF sputtering. The process of forming the n-type oxide semiconductor film 300 may also be performed at room temperature.

Subsequently, referring to FIG. 3, a p-type nickel oxide film 400 is formed on the n-type oxide semiconductor film 300.

The p-type nickel oxide film 400 may be formed by a reactive sputtering method. Specifically, the p-type nickel oxide film 400 may be formed, using a pure nickel or NiO target, and using argon (Ar) and oxygen (O₂). At this time, the ratios of argon and oxygen may be different from each other. That is, the ratio of argon may be higher than the ratio of oxygen. At this time, oxygen may have a ratio of 1 to 20% compared with argon.

When the oxygen exceeds 20% compared with argon, it may be difficult to form a quantum dot of a nickel oxide film, that is, a quantum dot structure. When the oxygen is less than 1% compared with argon, the oxide film components of the nickel oxide film may not be properly formed.

The quantum dot, that is, the quantum dot structure described above may perform the function of a protective film (surface passivation) on the surface of the zinc oxide film being in contact with the nickel oxide film. Thus, an exciton or exiton phenomenon which has not occurred in the past may occur.

All of the transparent conductive film 200, the n-type oxide semiconductor film 300 and the p-type nickel oxide film 400 may be deposited in-situ. That is, the transparent conductive film 200, the n-type oxide semiconductor film 300, and the p-type nickel oxide film 400 may be continuously formed in the same sputtering chamber.

The transparent photoelectric element formed by the method of FIGS. 1 to 3 may be in the same form as in the following first and second examples. However, the present invention is not limited thereto, and other possible modifications are naturally possible.

### First Example

A PET flexible substrate was used for the transparent substrate 100. The PET flexible substrate has no color and has a thickness of 100 μm. The PET flexible substrate was cleaned by ultrasonication of distilled water.

The transparent conductive film 200 was deposited as the ITO film. The ITO film may perform a sputtering process of an ITO target (10 wt. % SnO₂ containing In₂O₂) on the PET flexible substrate with an output density of 3.7 W/cm². During the ITO sputtering, argon and oxygen may be supplied at 30 sccm and 0.3 sccm, respectively. The ITO film was deposited with a thickness of 300 nm.

The n-type oxide semiconductor film 300 was deposited as a ZnO film. The ZnO film may be deposited by the RF sputtering system. At this time, the RF power may be 3.58 W/cm². The ZnO target can have a purity of 99.99%. The ZnO film was deposited to a thickness of 100 nm.

Finally, the p-type nickel oxide film 400 was formed by reactively sputtering a Ni target with purity of 99.999% at the output of 3.70 W/cm² in the presence of argon and oxygen gas. At this time, argon and oxygen gases are supplied at 30 sccm and 1 sccm, respectively. The operating pressure valve may be maintained at 5 mTorr. The base pressure before the operating pressure may be maintained at 5×10⁻⁵ Torr. The nickel oxide film was deposited with a thickness of 30 nm.

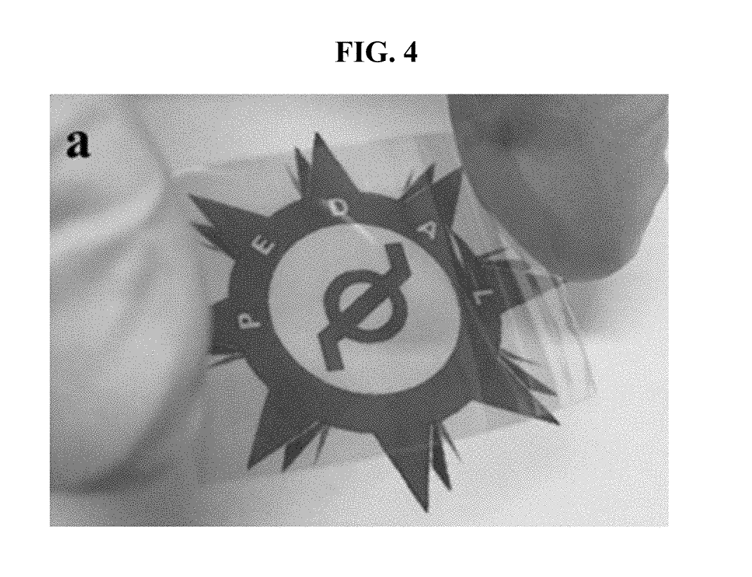

FIG. 4 is a digital photograph of the transparent photoelectric element of the first example fabricated using the method for fabricating the transparent photoelectric element of FIGS. 1 to 3. Referring to FIG. 4, it is possible to check that the transparent photoelectric element of the first example is totally transparent and easily bent.

### First Comparative Example

A nickel oxide film was directly deposited on the PET flexible substrate with a thickness of 30 nm by reactive sputtering.

### First Experimental Example

In order to investigate the characteristics of the interface of first example and first comparative example, the FESEM and HRTEM photographs of the respective interfaces were analyzed.

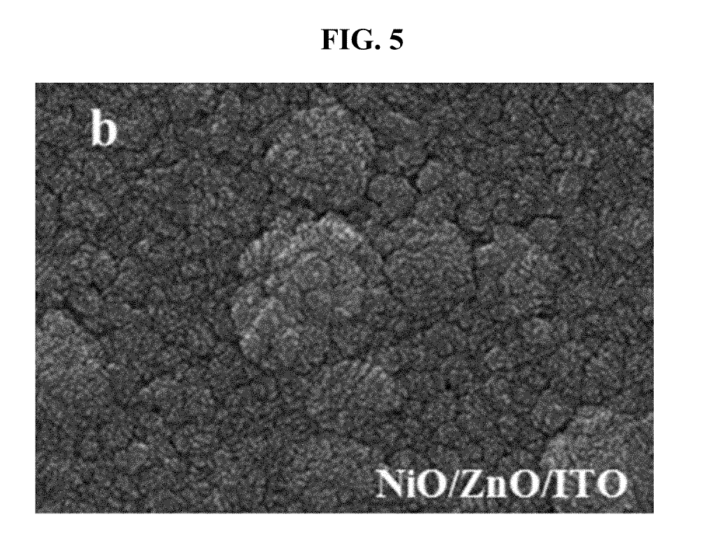

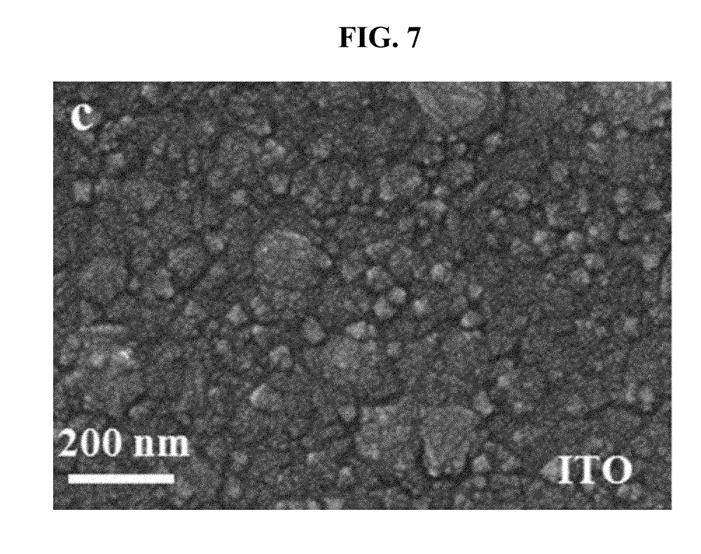

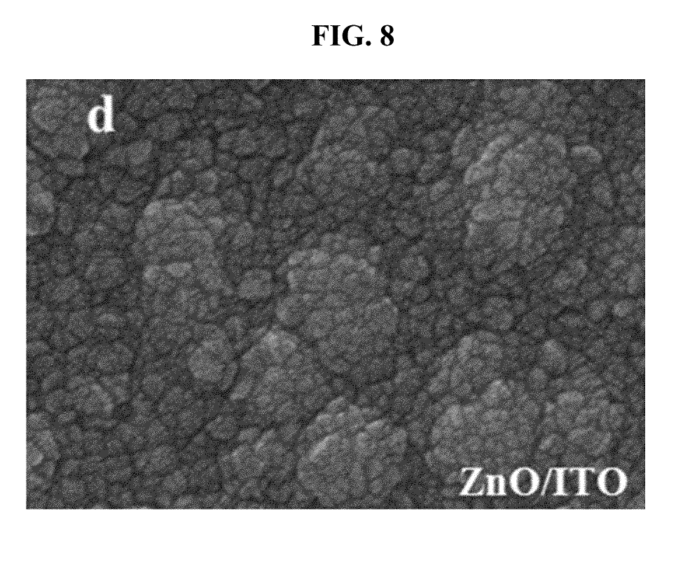

FIG. 5 is a FESEM (field emission scanning electron microscope) photograph of the surface of the nickel oxide film formed in the method for fabricating the transparent photoelectric element of FIGS. 1 to 3, and FIG. 6 is a photograph of the HRTEM (High-resolution transmission electron microscopy) photograph of the nickel oxide film fabricated by the reactive sputtering method. FIG. 7 is an FESEM photograph of the surface of an ITO (Indium Tin Oxide) film formed in the method for fabricating the transparent photoelectric element of FIGS. 1 to 3, and FIG. 8 is a FESEM photograph of the surface of the zinc oxide film formed in the method for fabricating the transparent photoelectric element of FIGS. 1 to 3.

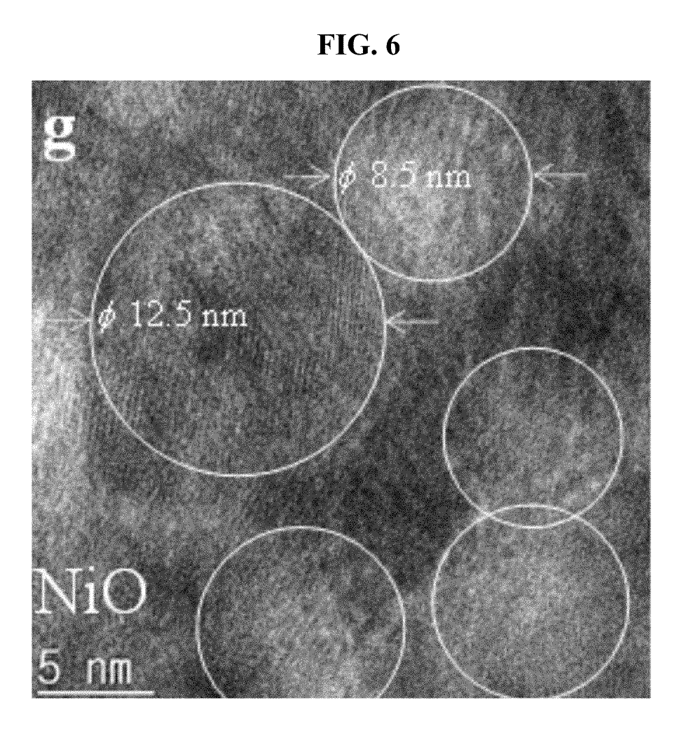

Referring to FIGS. 5 to 8, it is possible to understand that all of the ITO film, the ZnO film and the NiO film have a uniform polycrystalline structure. In particular, referring to FIG. 6, it is possible to check that the NiO film has a nanocrystalline structure and has a quantum dot structure. At this time, an average diameter of the quantum dot structure may be 7 to 9 nm.

Since the NiO film has the quantum dot structure, the energy level (or state) of the NiO film may have a discrete density divided into several sections. The energy levels with discrete density may very rapidly promote the transfer of holes separated from the exciton by incident light. Therefore, the photoresponse rate of the transparent photoelectric element of the first example of the present invention as a photodetector can be greatly improved.

Furthermore, since the NiO film has the quantum dot structure, the surface energy state of the interface between the NiO film and the ZnO film may be reduced. That is, the quantum dot structure of the NiO film may act as a passivation film on the surface of the ZnO film. As a result, the interface characteristics of the heterojunction of the NiO film and the ZnO film formed at room temperature can be greatly improved.

### Second Experimental Example

In order to examine the optical characteristics, the transmittance (T), the reflection (R) and the absorbance (A) of the transparent photoelectric element of the first example were examined.

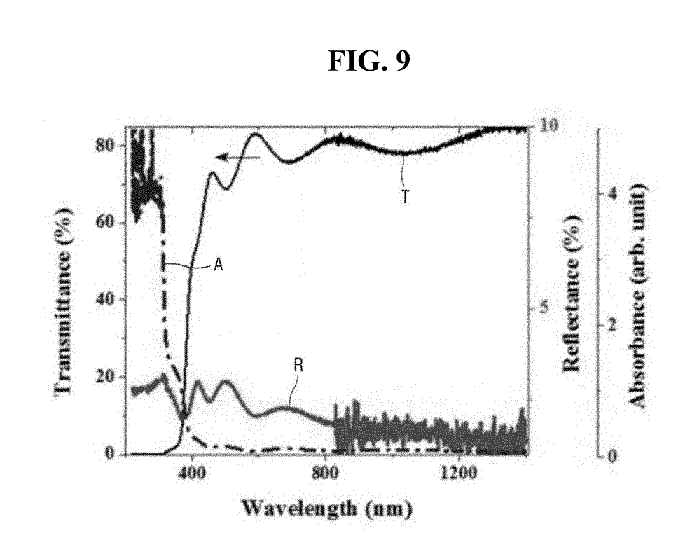

FIG. 9 is a graph illustrating transmittance, reflectance and absorbance spectra of the transparent photoelectric element according to the first example of the present invention.

Referring to FIG. 9, the transparent photoelectric element of the first example having a heterojunction of NiO and ZnO has a very high transmittance (visible ray region: 74.8%, infrared region: 81.8%). Further, the transparent photoelectric element of this example has a strong absorbance for UV photon. That is, the transparent photoelectric element of the first example may be a colorless transparent photoelectric element which strongly absorbs ultraviolet photon energy and simultaneously transmits visible ray well.

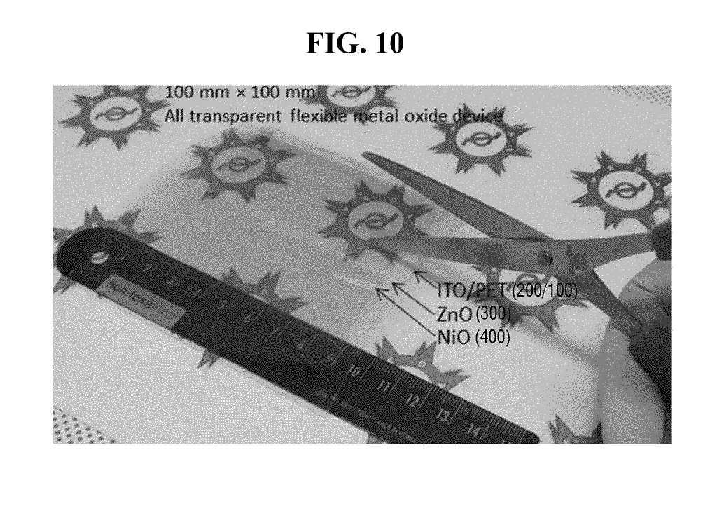

On the other hand, in order to investigate FIG. 9, the transparent photoelectric element of the first example may be cut into an appropriate size. FIG. 10 is a diagram for explaining a cutting way of the transparent photoelectric element according to the first example of the present invention.

Referring to FIG. 10, the transparent photoelectric element of the first example may be easily cut with scissors. Of course, the transparent photoelectric element may be easily cut with a simple cutting tool such as a knife as well as scissors. Therefore, the transparent photoelectric element of the first example of the present invention may be produced on a large scale and then may be easily cut into desired size. Further, the transparent photoelectric element may also be easily attached at a desired position with a desired size through lightweight and easy cutting characteristics.

### Third Experimental Example

TEM (transmission electron microscopy) and EDS (energy-dispersive X-ray spectroscopy) were analyzed to check the interface characteristics of the transparent photoelectric element of the first example.

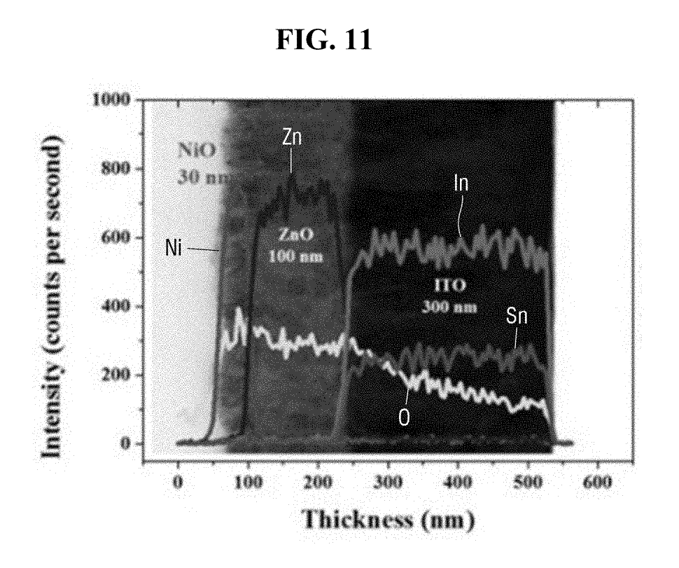

FIG. 11 is a diagram illustrating TEM (transmission electron microscopy) and EDS (energy-dispersive X-ray spectroscopy) for cross-sectional analysis of the transparent photoelectric element according to the first example of the present invention.

Referring to FIG. 11, it is possible to understand that the thicknesses of the ITO film, the ZnO film and the NiO film are clearly expressed as 30 nm, 100 nm, and 300 nm, respectively. In addition, it is possible to check that each component is also clearly illustrated.

### Fourth Experimental Example

In order to investigate the characteristics as an ultraviolet photodetector, the transparent photoelectric element of the first example was mounted on an ultraviolet ray source (365 nm wavelength, 3 mW/cm²).

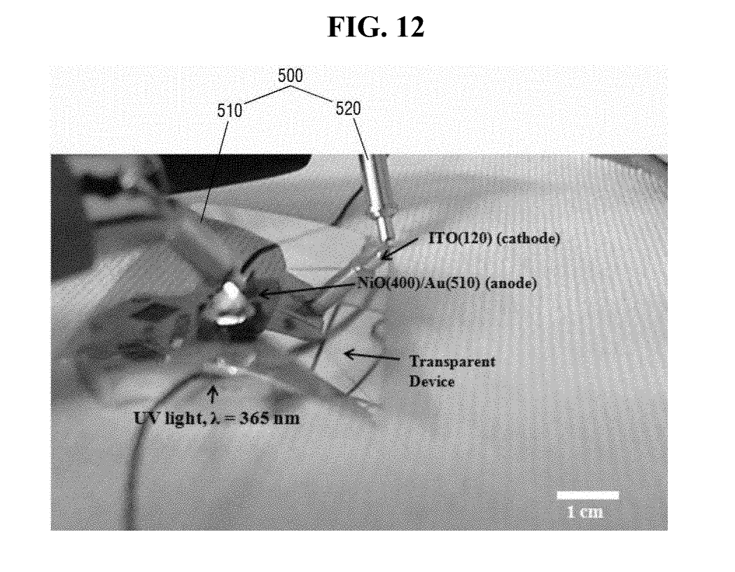

FIG. 12 is a diagram illustrating a test scene in which ultraviolet rays of 365 nm are incident on the transparent photoelectric element according to the first example of the present invention.

Referring to FIG. 12, a probe can be brought into contact with the transparent conductive film 200 and the NiO film 400, respectively, by mounting the transparent photoelectric element of the first example on the ultraviolet ray source. At this time, the ITO film cathode which is the transparent conductive film 200 may be used as a cathode, and the NiO film 400 may be used as an anode.

The probe 500 includes a first probe 510 and a second probe 520 corresponding to the anode and the cathode, respectively. At this time, the first probe 510 may be brought into contact with the ITO film, and the second probe 520 may be brought into contact with the NiO film.

At this time, the transparent photoelectric element of the first example does not include any opaque electrode, and the probe 500 may include tungsten coated with Au, but is not limited thereto.

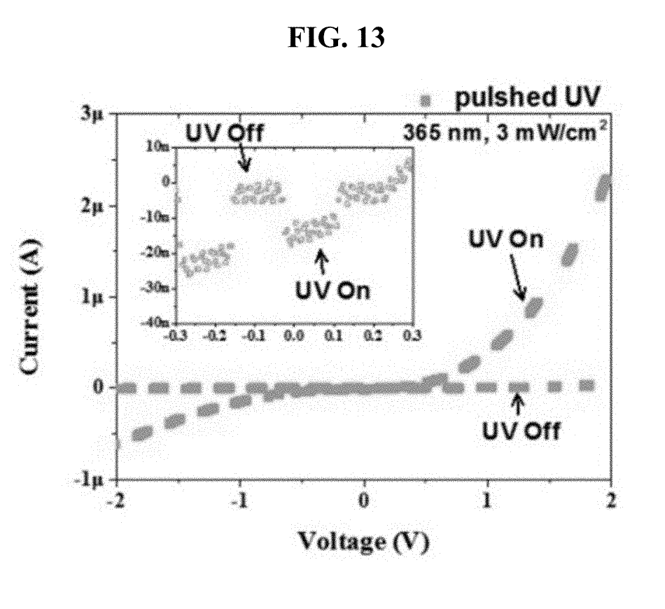

FIG. 13 is a graph illustrating the current-voltage characteristics of the transparent photoelectric element according to the test of FIG. 12 under the pulsed incident light condition.

Referring to FIG. 13, the transparent photoelectric element of the first example may exhibit a clear photoresponse under the zero bias condition.

### Fifth Experimental Example

In order to evaluate the transparent photoelectric element of the first example as a self-bias photodetector, the intensity of ultraviolet ray was changed from 10 μW/cm² to 3 mW/cm².

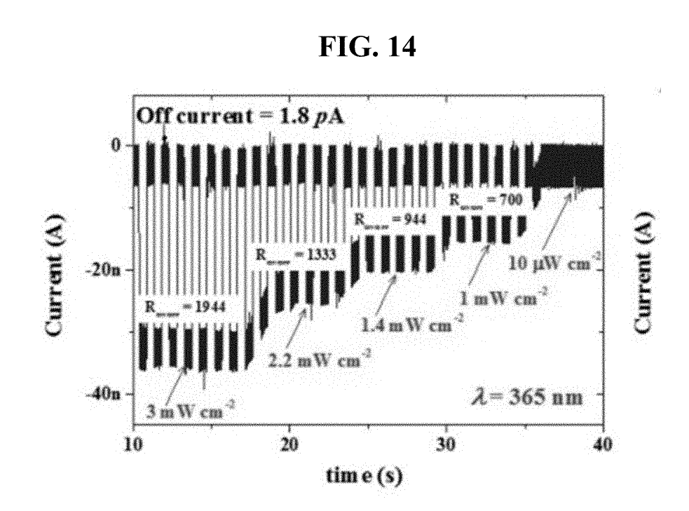

FIG. 14 is a graph illustrating the zero bias device operation of the transparent photoelectric element according to the first example of the present invention and the light intensity effect of the instantaneous photoresponse.

The photoresponse ratio PR, which is an important factor in the photodetector, is a ratio of a light-on current I_{ON} and a light-off current I_{OFF}. That is, the photoresponse ratio is defined as PR=I_{ON}/I_{OFF}.

Referring to FIG. 14, I_{ON} increases by a stable noise current (I_{OFF} ˜1.8 pA) which is proportionally maintained as the intensity of UV rises. When the light intensity is 3 mW/cm², a high PR value of 1944 may be obtained.

Furthermore, the self-biased photodetector according to the first example is very sensitive and may detect extremely small ultraviolet ray such as 10 μW/cm².

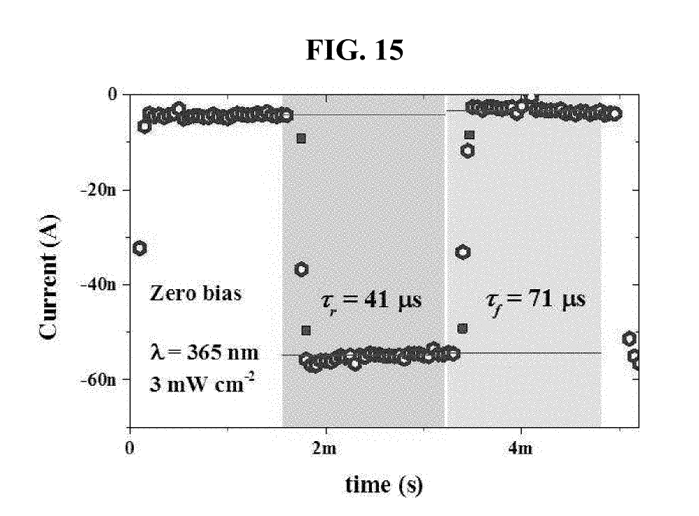

In order to evaluate the instantaneous photoresponse of the transparent photoelectric element of the first example, the photoresponse time was detected. FIG. 15 is a graph for instantaneous photoresponse analysis of the transparent photoelectric element according to the first example of the present invention.

Referring to FIG. 15, a rise time τᵣ and a pole time τ_{f} were measured as 41 μs and 71 μs at pulsed UV (3 mW/cm²), respectively. This may be understood as a result of resolving the poor photoresponse of the metal oxide due to strong exciton optical absorption and the photoresponse associated with oxygen.

### Sixth Experimental Example

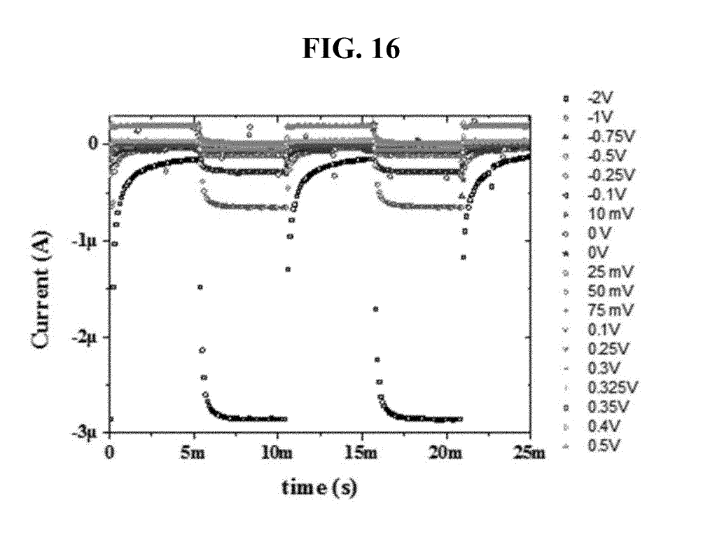

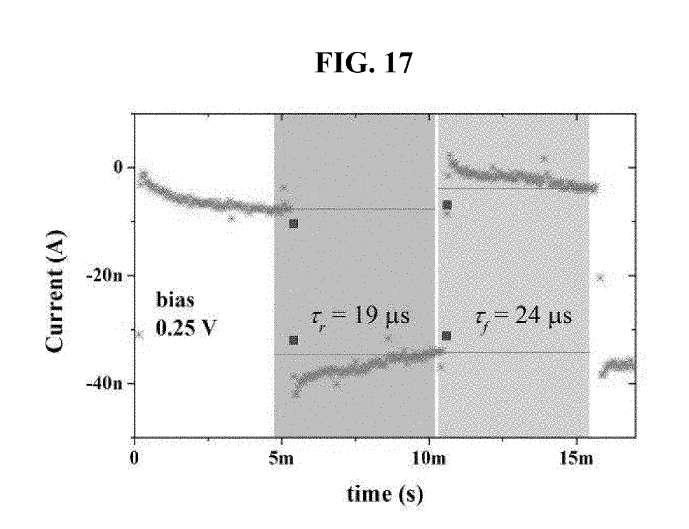

Various voltages were applied to the transparent photoelectric element of the first example in order to evaluate the bias-responses of the transparent photoelectric element of the first example. FIG. 16 is a graph for explaining photoresponse and the effect of bias of the transparent photoelectric element according to the first example of the present invention, and FIG. 17 is a graph for explaining the instantaneous photoresponse of the transparent photoelectric element according to the first example of the present invention.

Referring to FIGS. 16 and 17, the photoresponse may be improved to τᵣ=19 μs and τ_{f}=24 μs under the forward bias condition (0.25 V). This may be the fastest photoresponse in the photodetector of the NiO/ZnO junction.

The rapid photoresponse may be attributed to the regulatory effect of the space charge region. When an electric field is applied to the exciton, the separated charges and holes move in opposite directions. According to the Bore model, the free exciton's energy is the same as 2 Rx/(qaₓ) in the ground state. Here, Rx is the rydberg energy of the exciton, q is the charge of the electrons, and ax is a bore radius of the polycrystalline ZnO. If the electric field exceeds the value of free exciton, exciton may be separated by field ionization.

In the transparent photoelectric element of the first example of the present invention, as the applied bias is adjusted, it is possible to acquire a much faster photoresponse by efficient formation of generation of free excitons and efficient separation according to field ionization.

An important evaluation factor of a photodetector is response R* and detection D*. The responsen is defined by R*=Iₚₕ/Pᵢₙ where Iₚₕ and Pᵢₙ mean the photocurrent and the light intensity, respectively. The detection is defined by D*=R*/(2qJ_{d})^{1/2} where J_{d} means the background current density.

Three types of bias conditions (zero bias in the self-operating mode, forward bias in the field ionization mode, and reverse bias in the photoconductive mode) may be given to the photodetector using the transparent photoelectric element of the first example.

Under the zero bias condition, response and detection are exhibited as 20 μA/W and 7.2×10¹¹ Jones, respectively. Performance of enhanced response (1 mA/W) and detection (4.58×10¹² Jones) is obtained in the photoconductive mode. However, the photoresponse (τᵣ=370 μs and τ_{f}=840 μs) may be delayed by its own intrinsic operation mode, unlike the rapid photoresponse of the field ionization mode. That is, the photodetector of the transparent photoelectric element of the first example of the present invention may have excellent photodetection characteristics and enhanced performance intentionally selected in a special mode.

### Seventh Experimental Example

In order to evaluate the characteristics of the transparent photoelectric element of the first example as a solar cell, the voltage-current characteristics under the dark condition and the illumination condition were measured.

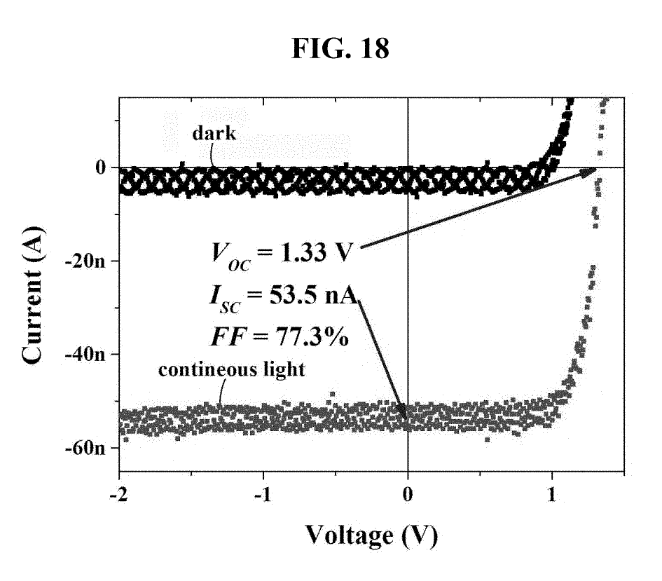

FIG. 18 is a graph for explaining current-voltage characteristics of the transparent photoelectric element according to the first example of the present invention.

Referring to FIG. 18, it is possible to understand that the transparent photoelectric element according to the first example has very clean rectifying characteristics with a very low saturation current of 0.1 nA. A very high rectifying ratio exceeding 7000 occurs at +2V to −2V. At this time, the rectifying ratio may mean a value obtained by dividing the current value at 2 V by the current value at −2 V.

At the incidence of ultraviolet ray (λ=365 nm, 3 mW/cm²), the transparent photoelectric element of the first example apparently provides photovoltaic characteristics of a very large open circuit voltage (Voc) of 1.33 V, a short circuit current density (Jsc) of 27.2 μA/cm², and a fill factor (FF) of 77.3%.

The photoelectric element according to the first example of the present invention is a photodetector and a solar cell, which has an ultrafast photoresponse, does not need a metal contact, is totally transparent, is flexibly bent and then restored, and is very light. Therefore, through these advantages, the photoelectric element may be variously applied in the field of solar cells. For example, the photoelectric element of the first example of the present invention may be used as a transparent film integrated in a window of a building or a vehicle. Such a transparent film can achieve the ultimate goal of energy management to generate on-site power.

### Second Example

As the transparent substrate, a glass substrate was used. A transparent conductive film 200 was deposited as the FTO film. The FTO film was coated on the glass substrate. The n-type oxide semiconductor film 300 was deposited as a ZnO film, and a p-type nickel oxide film 400 was deposited thereon. In other words, the NiO/ZnO/FTO/glass structure was finally formed.

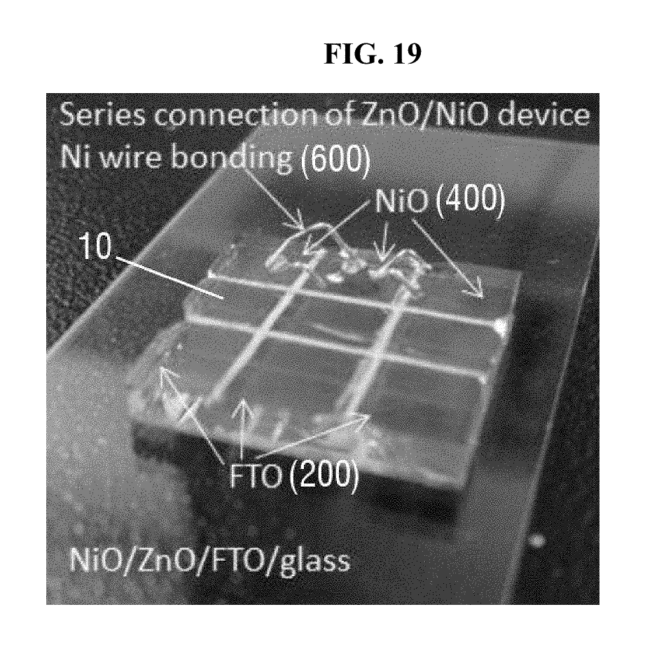

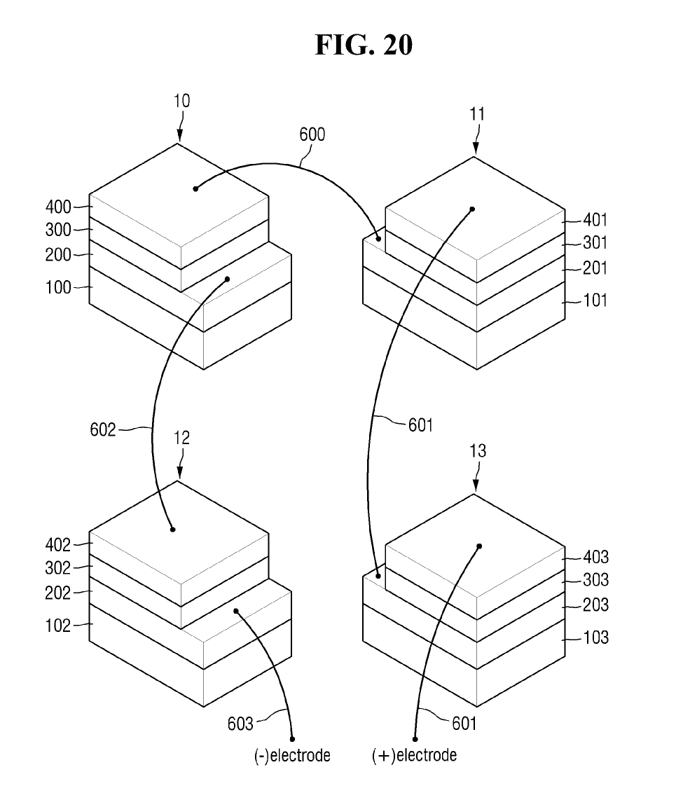

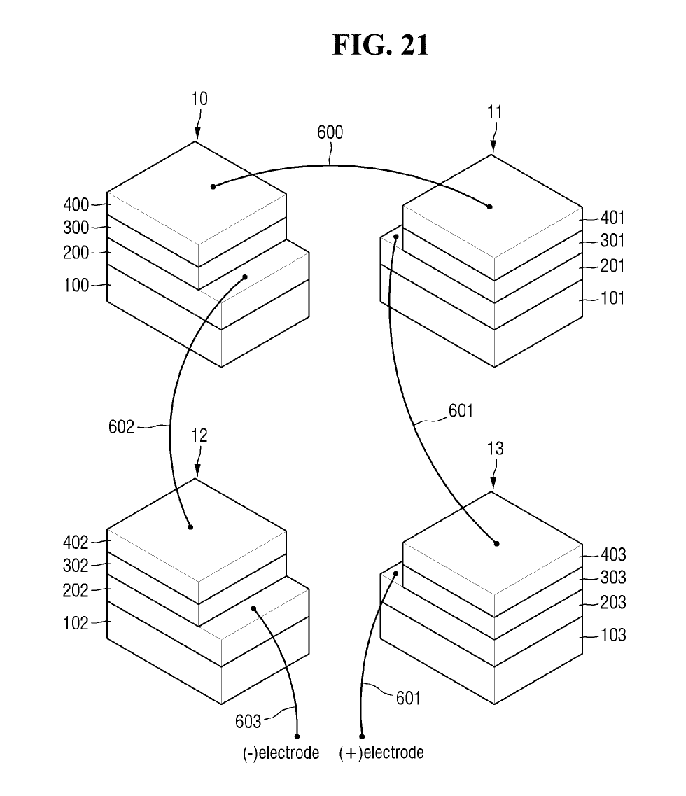

FIG. 19 is a digital photograph for explaining the arrangement of the transparent photoelectric element of the second example of the present invention, and FIG. 20 is a diagram for explaining the series connection of the transparent photoelectric element of the second example of the present invention. FIG. 21 is a diagram for explaining the parallel connection of the transparent photoelectric elements according to the second example of the present invention.

Referring to FIG. 19, the transparent photoelectric element of the second example may be divided into sectors by the diamond chip so as to be electrically separated from each other. As a result, nine solar cell units insulated from each other may be gathered to form a single solar cell module. The separated solar cell unit may be connected with a nickel wire.

At this time, the transparent photoelectric element before separation may have, but is not limited to, a size of 3 mm×3 mm.

Referring to FIG. 20, the transparent photoelectric element of the second example of the present invention may include a plurality of units. For example, the transparent photoelectric element of the second example of the present invention may include a first transparent photoelectric element unit 10, a second transparent photoelectric element unit 11, a third transparent photoelectric element unit 12, and a fourth transparent photoelectric element unit 13. Although four units are illustrated in the drawing, this is merely an example, and is not limited thereto.

The first transparent photoelectric element unit 10 may include a first transparent substrate 100, a first transparent conductive film 200, a first n-type oxide semiconductor film 300, and a first p-type nickel oxide film 400. The second transparent photoelectric element unit 11 may include a second transparent substrate 101, a second transparent conductor film 201, a second n-type oxide semiconductor film 301, and a second p-type nickel oxide film 401. The third transparent photoelectric element unit 12 may include a third transparent substrate 102, a third transparent conductor film 202, a third n-type oxide semiconductor film 302, and a third p-type nickel oxide film 402. The fourth transparent photoelectric element unit 13 may include a fourth transparent substrate 103, a fourth transparent conductor film 203, a fourth n-type oxide semiconductor film 303, and a fourth p-type nickel oxide film 403.

The first to fourth transparent photoelectric element units 10 to 13 may be connected in series to each other. At this time, the first p-type nickel oxide film 400 of the first transparent photoelectric element unit 10 and the second transparent conductor film 201 of the second transparent photoelectric element unit 11 may be connected to each other by a first bonding wire 600.

Similarly, the third p-type nickel oxide film 402 of the third transparent photoelectric element unit 12 and the first transparent conductive film 200 of the first transparent photoelectric element unit 10 may connected to each other by a third bonding wire 602.

The second p-type nickel oxide film 401 of the second transparent photoelectric element unit 11 and the fourth transparent conductor film 203 of the fourth transparent photoelectric element unit 13 may connected to each other by a second bonding wire 601.

The fourth bonding wire 603 may mutually connect the third transparent conductive film 202 of the third transparent photoelectric element unit 12 and the (−) electrode, and the fifth bonding wire 604 may mutually connect the−fourth p-type nickel oxide film 403 of the fourth transparent photoelectric element unit 13 and the (+) electrode. At this time, the fourth bonding wire 603 and the fifth bonding wire 604 may be omitted.

As illustrated in FIG. 20, the transparent photoelectric elements of the second example may be connected in series. Unlike this, referring to FIG. 21, it is also possible to connect the transparent photoelectric elements of the second example in parallel.

At this time, the first p-type nickel oxide film 400 of the first transparent photoelectric element unit 10 and the second p-type nickel oxide film 401 of the second transparent photoelectric element unit 11 may be connected to each other by the first bonding wire 600.

Further, the second transparent conductive film 201 of the second transparent photoelectric element unit 11 and the fourth p-type nickel oxide film 403 of the fourth transparent photoelectric element unit 13 may be connected to each other by the second bonding wire 601. Furthermore, the fifth bonding wire 604 may mutually connect the fourth transparent conductive film 203 of the fourth transparent photoelectric element unit 13 and the (+) electrode.

Referring to FIG. 19, nine units of 3×may be gathered to form a single module. At this time, each unit may be connected as required by free ways of series or parallel connection.

### Eighth Experimental Example

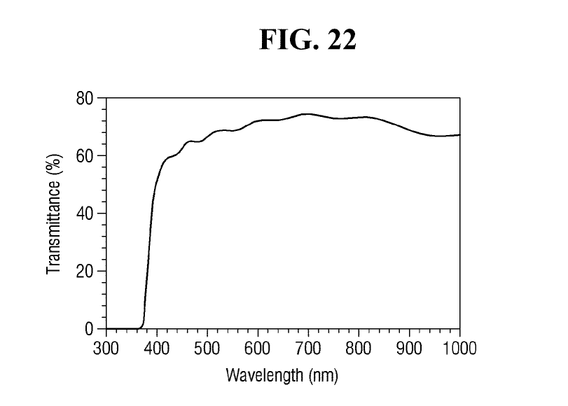

The transmittance of the transparent photoelectric element module of the second example was measured. FIG. 22 is a graph illustrating the transmittance of the transparent photoelectric element of the second example of the present invention. Referring to FIG. 22, it is possible to check that the transparent photoelectric element of the second example of the present invention has a high transmittance of 69.6%.

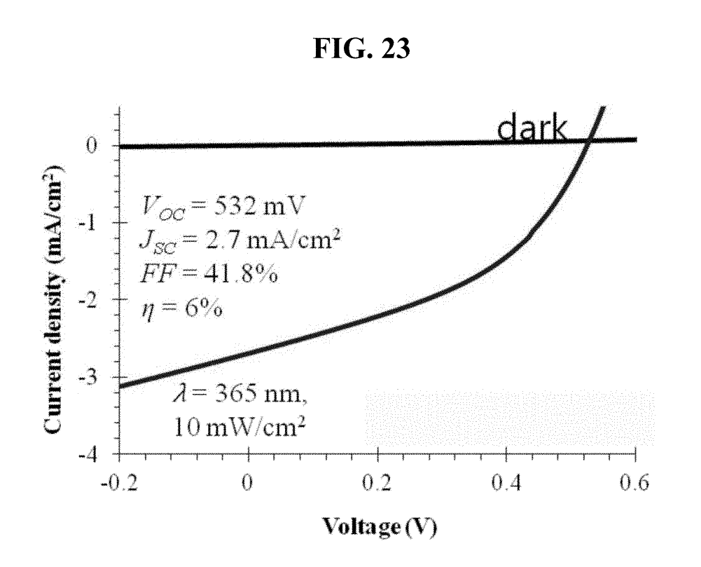

Further, in order to investigate the performance of the photoelectric element unit of the second example before the series connection, ultraviolet ray (λ=365 nm, 10 mW/cm²) was applied to the photoelectric element unit of the second example before the series connection or the parallel connection. FIG. 23 is a diagram for explaining the voltage-current characteristics of the transparent photoelectric element unit of the second example of the present invention.

Referring to FIG. 23, it is possible to obtain excellent current-voltage characteristics of V_{oc}=532 mV and J_{sc}=2.7 mA/cm².

In this way, the transparent photoelectric element of the second example of the present invention is a transparent solar cell module, which may be used as a power generation solar cell installed in a window of a building or a vehicle, a glass cover of a mobile phone or the like.

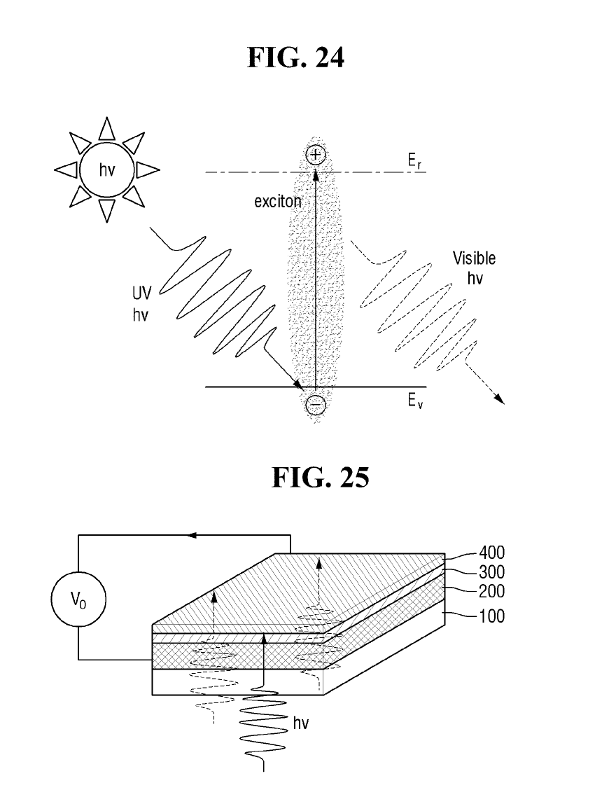

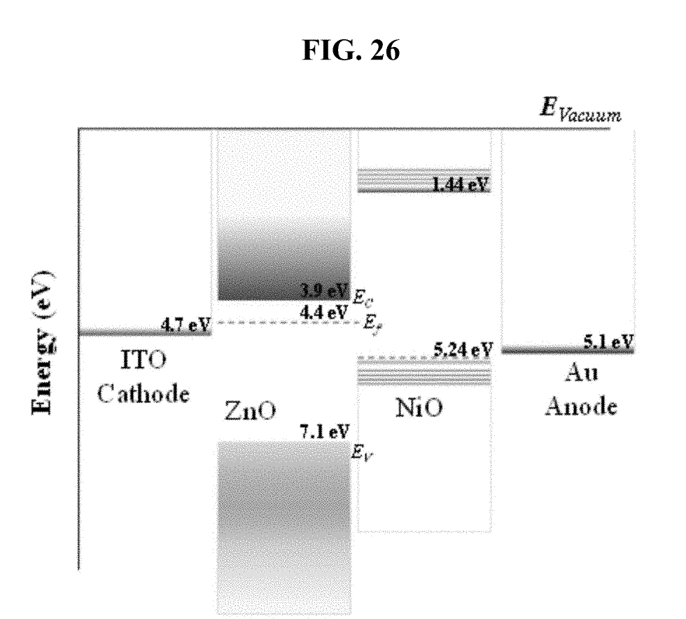

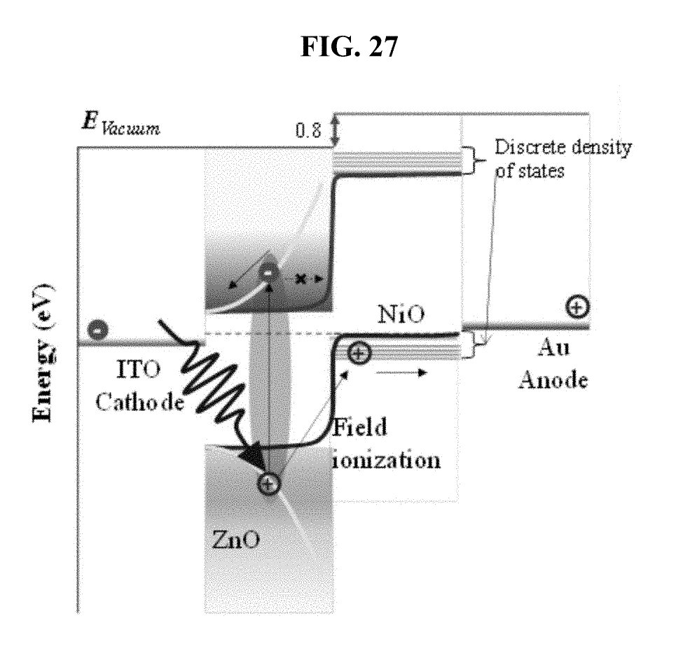

FIG. 24 is a conceptual diagram for explaining an occurrence of exciton of the transparent photoelectric element according to some embodiments of the present invention, and FIG. 25 is a conceptual diagram for explaining utilization of ultraviolet rays of the transparent photoelectric element according to some embodiments of the present invention. FIG. 26 is an energy band diagram for explaining energy levels in a balanced condition of the transparent photoelectric element according to some embodiments of the present invention, and FIG. 27 is an energy band diagram for illustrating the energy level when the transparent photoelectric element according to some embodiments of the present invention forms exciton.

Referring to FIGS. 24 to 26, free excitions of electron-hole pairs mutually bound by Coulomb force may move at the same group velocity within the lattice cell arrangement until the free excitions are separated into free electrons and free holes. According to the design of forming the transparent NiO/ZnO heterojunction on the ITO or TCO transparent conductive film 200 of the present invention (FIG. 25), the transparent conductive film 200 may serve as a transparent conductive layer, the ZnO film may function as a ultraviolet photon absorption film, and the NiO film may function as a transmission film of hole, while forming a heterojunction with the ZnO film.

The energy band edge illustrated in FIG. 26 illustrates a configuration in which the polycrystalline ZnO film has a stepwise energy level in the balance band and in the conduction band, and meanwhile, the NiO film has the discrete density of the state in the quantum dots forming the nanocrystalline NiO film.

The NiO film forms a potential barrier of 0.8 eV of ZnO film as the NiO film and the ZnO film are bonded (FIG. 27). Such a potential barrier provides a very small extent of dark current (<0.1 nA) in the dark condition. Under the condition in which ultraviolet rays are incident, ultraviolet photon absorption generates free excitons which can move to the lattice of the ZnO film. Due to the relatively large binding energy, free excitions may survive even with less loss of thermalization.

Ultraviolet-reactive ZnO/NiO heterojunction induces field ionization to separate excitons of free carriers. At this time, the NiO film may actively collect the holes.

On the other hand, the transparent conductive film 200 allows for high Voc during operation of the solar cell, which is capable of drawing electrons. That is, although the separated free electrons are difficult to move to the NiO film due to the existence of the potential barrier, since the free electrons easily search for a lower energy level, they move to the transparent conductive film 200. At this time, the discrete energy level of the NiO film accelerates the hole movement and may cause a very rapid instantaneous reaction. Accordingly, the transparent photoelectric element according to some embodiments of the present invention can have high transmittance and rapid photoresponse.

### Ninth Experimental Example

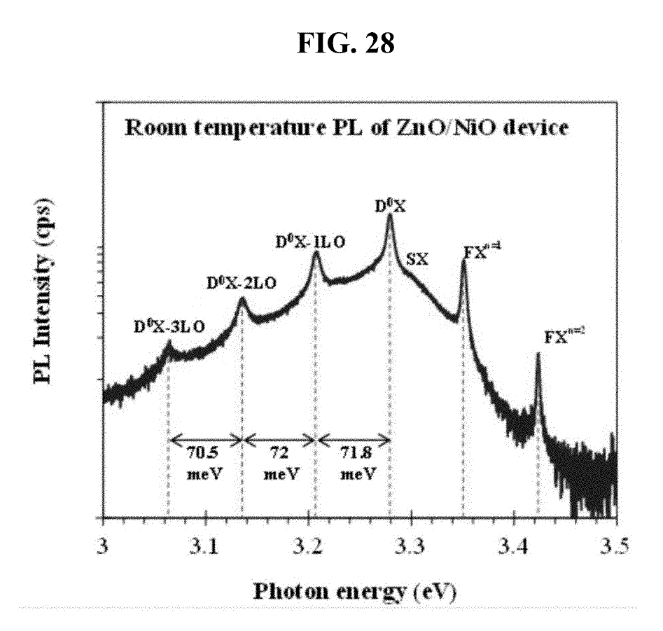

In order to investigate the crystalline quality and the exciton structure, photoluminescence (PL) of the ZnO/NiO heterojunction was measured at room temperature with a laser of 355 nm and was recorded as a reflection mode. FIG. 28 is a graph for explaining a photoluminescence spectrum of the transparent photoelectric element according to some embodiments of the present invention.

Referring to FIG. 28, the highest peak was formed at 3.28 eV when PL was illustrated on a semi-logarithmic scale. This intensive and sharp peak corresponds to neutral-donor-bound exciton line of ZnO which affects radiative recombination.

In the high energy region, free exciton (FX) markedly appears and exhibits a strong FXⁿ⁼¹ peak at 3.351 eV. The first excited-state emission exciton is clearly observed at FXⁿ⁼²=3.423 eV. In addition to such a peak, the higher energy region of D⁰X also exhibits some hills due to recombination of donor-like surface excitons (SX) at 3.315 eV.

Considering the exciton binding energy (60 meV) of ZnO, the exciton easily remains at room temperature. The longitudinal optical (LO) phonon duplicate line of dominant D⁰X emission shows a regular array shape. Replicated lines of the primary (1LO), secondary (2LO) and tertiary (3LO) of D⁰X emissions move in the direction of lower energy by about 72 meV from the main D⁰X emission. The location of the PL peak may be evidence of a high-quality ZnO film or one-dimensional nanostructure at low temperature measurement conditions. Polycrystalline ZnO obviously provides a PL peak at room temperature. Due to the quantum dot structure of NiO, the NiO film may act as a surface protective film of the ZnO film. As a result, a clear P1 peak is induced at room temperature, and it is possible to demonstrate the reduced surface states according to the formation of the ZnO/NiO surface.

While the present invention has been particularly illustrated and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A method for fabricating a transparent photoelectric element, the method comprising:
providing a transparent substrate;
forming a transparent conductive film on the transparent substrate at room temperature;
forming an n-type oxide semiconductor film on the transparent conductive film; and
forming a p-type nickel oxide film having a quantum dot structure on the n-type oxide semiconductor film through reactive sputtering at room temperature,
the reactive sputtering including oxygen and argon,
a ratio of oxygen being smaller than a ratio of argon.

2. The method of claim 1, wherein the transparent conductive film is in direct contact with the substrate and the n-type oxide semiconductor film, and
the p-type nickel oxide film is in direct contact with the n-type oxide semiconductor film.

3. The method of claim 1, wherein the ratio of oxygen corresponds to 1 to 20% of the ratio of argon.

4. The method of claim 1, wherein the substrate is a flexible substrate.

5. The method of claim 4, wherein the substrate is a plastic substrate, and the method further comprises:
cutting the transparent photoelectric element to a specific size; and
attaching the transparent photoelectric element to a target object.

6. The method of claim 1, wherein the substrate is a glass substrate,
the transparent photoelectric element includes first and second transparent photoelectric elements having the same structure, and
the first and second transparent photoelectric elements are electrically connected to each other.

7. The method of claim 6, wherein electrically connecting the first and second transparent photoelectric elements comprises:
electrically connecting the transparent conductive film of the first transparent photoelectric element and the p-type nickel oxide film of the second transparent photoelectric element.

8. The method of claim 6, wherein electrically connecting the first and second transparent photoelectric elements comprises:
electrically connecting the p-type nickel oxide film of the first transparent photoelectric element and the p-type nickel oxide film of the second transparent photoelectric element.

9. The method of claim 6, wherein electrically connecting the first and second transparent photoelectric elements comprises:
connecting the first and second transparent photoelectric elements to each other via a bonding wire.

10. The method of claim 1, wherein the n-type oxide semiconductor film comprises at least one of ZnO, AZO, TiO and SnS.

11. The method of claim 1, wherein the transparent conductive film is ITO or FTO.

12. The method of claim 1, wherein the formation of the transparent conductive film, the n-type oxide semiconductor film, and the p-type nickel oxide film are performed in-situ.

13. A transparent photoelectric element comprises:
a transparent flexible PET (polyethylene terephthalate) substrate;
a transparent conductive film formed on the transparent flexible PET substrate, the transparent conductor including ITO (Indium Tin Oxide) or FTO (fluorine-doped tin oxide);
an n-type oxide semiconductor film formed on the transparent conductive film; and
a p-type nickel oxide film formed on the n-type oxide semiconductor film and forming a heterojunction with the n-type oxide semiconductor film,
wherein exciton occurs in the heterojunction, and
the p-nickel oxide film has a quantum dot structure.

14. The transparent photoelectric element of claim 13, wherein an average diameter of the quantum dot structure is 1 to 30 nm.

15. A transparent photoelectric element comprising:
a first laminated structure which includes a first glass substrate, a first transparent conductor film formed on the first glass substrate, a first FTO film formed on the first transparent conductor film, and a first NiO film formed on the first FTO film and forming a heterojunction with the first FTO film;
a second laminated structure which includes a second glass substrate, a second transparent conductor film formed on the second glass substrate, a second FTO film formed on the second transparent conductor film, and a second NiO film formed on the second FTO film and forming a heterojunction with the second FTO film; and
a bonding wire which connects the first and second laminated structures.

16. The transparent photoelectric element of claim 15, wherein the first and second NiO films have a nanocrystalline structure.

17. The transparent photoelectric element of claim 16, wherein the first and second NiO films have a quantum dot structure.

18. The transparent photoelectric element of claim 17, wherein an average diameter of the quantum dot structure is 1 to 30 nm.

19. The transparent photoelectric element of claim 15, wherein the bonding wire connects the first NiO film and the second FTO film.

20. The transparent photoelectric element of claim 15, wherein the bonding wire connects the first NiO film and the second NiO film.

21. The transparent photoelectric element of claim 15, further comprising:
third to ninth laminated structures having the same structure as the first and second laminated structures,
the first to ninth laminated structures being aligned in three rows and three columns.
